(19) United States
(12) Patent Application Publication
(10) Pub. No.: US 2011/0281380 A1
(43) Pub. Date: Nov. 17, 2011

(54) PROBE CARD AND METHOD OF MANUFACTURING SEMICONDUCTOR INTEGRATED CIRCUIT DEVICE

(75) Inventors: Yasunori NARIZUKA, Hiratsuka (JP); Etsuko Takane, Yokohama (JP); Akio Hasebe, Kanagawa (JP)

(73) Assignee: RENESAS ELECTRONICS CORPORATION

(21) Appl. No.: 13/107,317

(22) Filed: May 13, 2011

(30) Foreign Application Priority Data
May 13, 2010 (JP) JP2010-111437

(51) Int. Cl. H01L 21/66; G01R 31/00

(52) U.S. Cl. 438/17; 324/756.03; 257/E21.521

(57) ABSTRACT

Provided is a probe card for LSI inspection that can achieve electrical conduction to electrodes on an LSI with a low load without damaging the electrodes and a structural body therebelow, even if the electrodes are arranged at a narrow pitch and in a complex manner. A contact terminal is formed in a truncated square pyramidal recess provided on a film-shaped probe. A dent is often formed on a surface of the film-shaped probe just above the contact terminal. A resin coating film is formed so as to eliminate the dent and flatten the surface of the film-shaped probe. At this time, it is preferred that an amount of cure shrinkage of a resin paste for forming the resin coating film is 0.1% or less.

### CROSS-REFERENCE TO RELATED APPLICATIONS

The present application claims priority from Japanese Patent Application No. 2010-111437 filed on May 13, 2010, the content of which is hereby incorporated by reference to this application.

### TECHNICAL FIELD

The present invention relates to a probe card and a manufacturing technique of a semiconductor device, and more particularly to a technique effectively applied to a probe card provided with a probe sheet formed by the method similar to the method of manufacturing a semiconductor integrated circuit and a process of manufacturing a semiconductor device including an inspection process performed by a semiconductor inspection apparatus having the probe card.

### BACKGROUND

FIG. 1 is a flowchart showing a general example of a flow of an inspection process for checking the quality of a formed circuit (generally referred to as “LSI”) in a manufacturing process of a semiconductor device in which a semiconductor integrated circuit is formed on a semiconductor wafer (hereinafter, simply described as “wafer”).

After the LSIs are fabricated on a wafer (Step S1001), the following roughly-classified three inspections are performed in a manufacturing process of the LSIs as shown in FIG. 1.

Initial inspection regarding operations of the LSIs is first performed in a wafer state in which semiconductor integrated circuits and electrodes have been formed to grasp the conduction state and the electric signal operation state of the semiconductor elements (Step S1002). Thereafter, a dicing process is performed to put the LSIs into the state of semiconductor chips (hereinafter, simply described as “chip”) (Step S1003).

After the dicing process, in order to remove the chips with a small operation margin and the chips unstable in terms of reliability, the semiconductor elements are operated under the conditions of a high temperature and a high application voltage to perform the burn-in inspection (Step S1004).

Then, before the semiconductor devices are shipped, the grade classification in terms of operations by means of the sorting inspection for grasping the performance of individual chips (Step S1005) and the appearance check (Step S1006) are performed.

Through these inspections, the chips having quality high enough to be shipped as products are selected, and they are processed into various packaging forms according to need (Step S1007). In recent years, from the viewpoint of the reduction in inspection cost, it has been required to perform a combined inspection of the Step S1001 and the Step S1004 so as to achieve the reduction in inspection time and remove defective LSIs in an early stage.

In an apparatus used for the inspection of LSIs like this (semiconductor inspection apparatus), a probe card is used as an inspection jig for inspecting the electrical properties of an LSI having many connection electrodes. FIG. 2 is a sectional view showing a structure of a typical probe card.

In the structure of this probe card, metal needles (probes) 202 made of hard metal such as tungsten and fixed so as to project obliquely and downwardly from a lower surface of a wiring board 201 are electrically connected to wirings on the board by solders 203 and the needles are fixed on the surface of the wiring board 201 by fixing resins 204.

In the inspection using this probe card, distal ends of the probes 202 are pressed onto electrodes of an LSI to form a mechanical contact and take electrical conductions, thereby inspecting the electrical properties of the LSI.

In recent years, the number of electrodes (pads) on an LSI has been increased with the improvement in integration degree of the LSIs and multi-functionality thereof, so that an arrangement pitch of electrodes has become narrower. As a result, narrow-pitch and multi-pin arrangement has also been advanced with respect to the probes on the probe card for inspection.

Along with the transition on an LSI side like this, in the above-described probes made of hard metal needles, it gradually becomes difficult to press the probes onto fine electrodes, which are arranged on an LSI at a narrow pitch, with high positional accuracy from the viewpoint of processing accuracy and assembling accuracy.

Furthermore, since the probes are arranged on a surface of a wiring board so as to correspond to the electrodes arranged at a narrow pitch, the hard metal needles constituting the probes must be made extremely thin. Therefore, the hard metal needles become easily deformable by pressing force, and they cannot withstand the repetitive pressings and are apt to be deformed.

In addition, occasions where the above-described Step S1002 is performed at a high temperature have also been increasing. At this time, the accuracy of distal positions of the needles remarkably lowers due to expansion and deformation of the metal needles at high temperature.

As described above, it cannot be said that the probes made of hard metal needles are suitable for the increase of the number of electrodes and the narrow-pitch arrangement of the electrodes, and the development of a probe card capable of achieving the electrical contact securely even in the case of the increase of the number of electrodes and the narrow-pitch arrangement has been demanded.

A probe card and an inspection method which have been developed in expectation of such a demand include the following techniques.

For example, pp. 601-607 of Proceedings of ITC (International Test Conference) 1988 (Non-Patent Document 1) describes a technique. FIG. 3 is a perspective (partially broken) view of a main portion of a probe described in the Non-Patent Document 1 and FIG. 4 is a schematic sectional view of a probe card described therein.

The probe for inspecting the conductor used here is a probe in a film-like shape (probe sheet). In this probe sheet, signal wirings 302 and auxiliary wirings 303 are formed on a surface of a flexible insulating resin sheet 301 by using a photolithography technique. Further, a ground layer 304 is formed on a lower surface of the insulating resin sheet 301. Semispherical bumps 306 formed by plating in through-holes 305 of the insulating resin sheet 301 provided at positions corresponding to electrodes of a semiconductor to be inspected are used as distal ends of the probes, that is, so-called contact terminals.

The film-shaped probe sheet is mechanically fixed after electrodes formed at distal ends of wirings 406 of a wiring board 401 are aligned with the wirings 302 and 303. Further, a supporting plate 402 is pressed onto a rear surface of the film-shaped probe sheet, thereby constituting a probe card.

The supporting plate 402 has a function of conducting support so that the film constituting the probes can form a flat surface and a function of pressing the probes onto electrodes on an LSI with a predetermined load by using supporting springs 403. In this film-shaped probe 405, the plated bumps 306 are used as contact terminals 404, and when the contact terminals 404 are pressed onto the electrodes on the LSI, the contact terminals 404 are rubbed onto the electrodes on the LSI by means of the behavior of the supporting springs 403. In this manner, the electrical conduction between the contact terminals 404 and the electrodes of the LSI is established.

The biggest problem in the technique disclosed in the Non-Patent Document 1 is that, since the contact terminals 404 are dome-shaped plated bumps 306 formed by the plating, insulating or semi-insulating oxide films and absorption layers existing on almost all electrode surfaces cannot be broken sufficiently. Accordingly, since high-electrical resistance contact often occurs and it obstructs accurate measurement of properties of an LSI in the inspection, there is a concern that a good product is misjudged as a defective product and the good product may be discarded. Because of this problem, the technique described in the Non-Patent Document 1 is not utilized for the production as it is.

Japanese Patent Application Laid-Open Publication No. 7-283280 (Patent Document 1) describes a technique for solving the problem of the instability of the contact resistance that is the problem in the technique described in the Non-Patent Document 1.

In an example described in the Patent Document 1, a square pyramidal or truncated square pyramidal bump formed by the process shown in FIGS. 5A to 5E is formed as a contact terminal.

FIGS. 5A to 5E are process diagrams regarding the formation of the square pyramidal or truncated square pyramidal bump described in the Patent Document 1.

More specifically, as shown in FIG. 5A, a square pyramidal or truncated square pyramidal recess 503 is formed by an anisotropic etching technique of silicon at a predetermined position on a surface of a silicon wafer 501 cut out in a specific plane direction. Thereafter, a whole surface of the silicon wafer 501 is covered with an oxide film 502.

Then, as shown in FIG. 5B, a hard metal film 506 is grown to fill the recess 503 by a pattern-electroplating technique using a plated base film 504 formed on the oxide film and a resist pattern 505. Further, as shown in FIG. 5C, a high-strength resin layer 507 made of polyimide or the like is formed on a pattern of the hard metal film 506, and a through-hole is then opened in the resin layer 507 on the pattern of the hard metal film 506 and a wiring 508 is formed by using a pattern-electroplating technique as shown in FIG. 5D. Finally, a film-shaped probe provided with a square pyramidal or truncated square pyramidal contact can be obtained by separating the structure formed on the surface of the silicon wafer 501 and the silicon wafer 501 from each other as shown in FIG. 5E.

### SUMMARY

However, as described above, the recent LSI is mounted with many circuits and therefore provided with the electrodes in the narrow-pitch and multi-pin arrangement.

FIG. 6 is a sectional view of a main portion showing a structure of elements and wirings of an LSI.

In addition, like in the sectional structure of the LSI shown in FIG. 6, wirings 603, 604, 605 and 606 mainly made of copper having low electrical resistance are formed on a silicon wafer 601 in order to transmit an electrical signal at high speed and with accuracy through wiring layers which connect elements 602.

Further, in order to speed up the electrical signal, a material much lower in dielectric constant than a silicon oxide film, which is a conventional material of an insulating layer, such as a low dielectric constant insulating film (low-k film) including a fluorine-doped silicon oxide film (FSG (fluorosilicate glass) film) and a silicon oxynitride film (SiON) has been used for interlayer insulating layers 607, 608 and 609. Most low-dielectric constant materials including these low-dielectric constant materials that have been used in recent years are porous materials for achieving a low dielectric constant and therefore are fragile, and weak against external force. For this reason, when the probes are strongly pressed onto electrodes on a surface of the LSI in the inspection of electrical operation, not only the electrodes but also the insulating layers 607, 608 and 609 formed under them are broken, and the wirings 603, 604, 605 and 606 may suffer such damages as short-circuit and disconnection, and the inspection may cause the breakage of the LSI.

Furthermore, in recent LSIs, a structure in which the electrodes are formed on the elements 602 has been increasingly applied in order to reduce the size of the LSI as much as possible. However, in the case of the structure like this, the contact of the probes with the electrodes applies the force from above, which may cause the abnormality in the operation of the element 602, and therefore there is a fear of the breakage of the LSI in the inspection also from this viewpoint. Even if the semiconductor elements 602 and the insulating layers 607, 608 and 609 that have been partly broken in the inspection may normally operate at the beginning, the breakage continues due to temperature change or the like during use, which may cause a problem in reliability such as the operation stop in a short time.

Therefore, the development of a probe that does not cause such abnormalities has been demanded.

The extent of the force that the LSI can bear against the breakage was examined by pressing the probe onto the electrode on an LSI in which a low-dielectric constant material which was materially fragile was used as insulating layers, and it was then found that the force that can be applied was a low load of 10 mN or less in terms of a force vertical to the electrode. This means that a probe capable of achieving the good electrical conduction with even such a low load is required.

Further, in addition to the suppression of a pressing load, the high accuracy in the positioning of a probe distal end is required in order to adapt to the narrow-pitch electrode arrangement. In addition, since the electrode is reduced in size, an influence of a scratch on the electrode formed by pressing the probe onto the electrode becomes unignorable, and even when the electrode is connected to an external circuit by wire bonding or forming a connection bump on the scratch, since there is a fear that this scratch may cause connection breakage, it is also required to reduce the scratch as much as possible.

An object of the present invention is to provide a probe card for LSI inspection that can achieve electrical conduction to electrodes with a low load without damaging the electrodes and a structural body therebelow even if the electrodes on the LSI are arranged at a narrow pitch and in a complex manner.

The above and other objects and novel characteristics of the present invention will be apparent from the description of the present specification and the accompanying drawings.

The following is a brief description of an outline of the typical invention disclosed in the present application.

A probe card according to a typical embodiment of the present invention includes: a plurality of contact terminals that are brought into contact with a plurality of electrodes mounted on an object to be inspected; pads formed integrally with the contact terminals; wirings extended from the respective pads; a resin film covering the pads and the wirings; and a film-shaped probe in which a plurality of peripheral electrodes electrically connected to the wirings and connected to electrodes on an external wiring board are formed, and on a rear surface on an opposite side to a main surface of the film-shaped probe on which the contact terminals are exposed, a resin paste is applied at least to a region corresponding to a portion immediately above the contact terminals, and is then cured.

In this probe card, a main component of the resin paste applied to the film-shaped probe is cured at room temperature or by heating, and a cured object thereof has a thermal resistance of 100° C. or higher.

In this probe card, an end of the region where the resin paste is applied is within 10 mm from one of the contact terminals that is closest thereto.

In this probe card, a difference in height in surface asperities of a resin layer on which the resin paste has been cured is 1 μm or less.

In this probe card, a plate member made of metal or ceramics is directly mounted on a resin after applying the resin paste or after curing the resin paste.

In this probe card, one or a plurality of resin sheets is mounted on the cured resin paste, and a plate member made of metal or ceramics is mounted on the one or the plurality of resin sheets.

In this probe card, the application and curing of the resin paste are performed during a process of forming the film-shaped probe.

In this probe card, the application and curing of the resin paste are performed in combination with inspection of contact properties of the film-shaped probe after assembly of the probe card.

In this probe card, the resin paste to be applied is a material having a percentage of cure volume shrinkage of 1% or less.

In this probe card, the resin paste is applied to a rear surface of the film-shaped probe above all the contact terminals formed on the probe card.

In this probe card, the resin paste is applied to a rear surface of the film-shaped probe above a specific terminal or a specific terminal group of the contact terminals formed on the probe card.

In this probe card, at least one elastomeric sheet is stacked on a surface of the film-shaped probe on an opposite side to the contact terminals, and a plate member made of metal or ceramics is mounted on the elastomeric sheet.

The effects obtained by typical embodiments of the invention disclosed in the present application will be briefly described below.

In the probe card according to the present invention made up of a film-shaped probe in which wirings extended from contact terminals are collectively formed, a pressing mechanism including a pressing plate and an elastomer and a wiring board on which these components are mounted, the asperities on a probe surface due to uneven arrangement of the components of the probe are removed from an upper surface of the film-shaped probe on which the contact terminals having a square pyramidal or truncated square pyramidal shape are formed, and therefore, the following effects can be achieved in addition to excellent properties of a conventional film-shaped probe such as the adaptability to a narrow pad pitch and a high positional accuracy of contacts.

(1) Even when contact inspection is performed to a lot of electrodes at a narrow pitch of 100 μm or less, the contact can be made with an even and low load, and therefore, the inspection can be performed without damaging a structural body below the electrodes even in the inspection of an LSI in which a dielectric material which is low in mechanical strength is used as an insulating layer.

(2) Even when contact inspection is performed to a lot of electrodes at a narrow pitch of 100 μm or less, the contact can be made with a low load, and therefore, sliding of the contact terminal on the electrode, which is likely to occur in a conventional film-shaped probe due to mechanistic elastic deformation or the like when the electrodes are pressed with a large load, can be prevented and scratches that occur during the contact are very small on any electrode surface, and even when a structure for connection to an external circuit such as a bonding wire or a bump is formed on the scratches, the structural body itself and the connection strength are not influenced at all. Therefore, an LSI with high reliability after the inspection can be provided. Further, since it is not necessary to avoid the scratches of the inspection when forming these structural bodies, the electrodes can be reduced in size, and therefore the LSI can also be reduced in size.

(3) As compared with a conventional film-shaped probe, an increase in the number of steps required to implement the present invention is small, and therefore an influence on manufacturing cost is also small.

### BRIEF DESCRIPTION OF THE DRAWINGS

FIG. 1 is a flowchart showing a general example of a flow of an inspection process for checking the quality of a formed circuit in a manufacturing process of a semiconductor device in which a semiconductor integrated circuit is formed on a semiconductor wafer;

FIG. 2 is a sectional view showing a structure of a typical probe card;

FIG. 3 is a perspective (partially broken) view of a main portion of a probe;

FIG. 4 is a schematic sectional view of a probe card;

FIG. 5A is a process diagram regarding the formation of a square pyramidal or truncated square pyramidal bump described in the Patent Document 1;

FIG. 5B is a process diagram continued from FIG. 5A;

FIG. 5C is a process diagram continued from FIG. 5B;

FIG. 5D is a process diagram continued from FIG. 5C;

FIG. 5E is a process diagram continued from FIG. 5D;

FIG. 6 is a sectional view of a main portion showing a structure of elements and wirings of an LSI;

FIG. 7A is an explanatory diagram showing a contact operation of a probe using a metal needle to an electrode;

FIG. 7B is an explanatory diagram continued from FIG. 7A;

FIG. 7C is an explanatory diagram continued from FIG. 7B;

FIG. 8A is an explanatory sectional view for improving the contact properties of a film-shaped probe;

FIG. 8B is an explanatory sectional view for improving the contact properties of a film-shaped probe;

FIG. 9A is a sectional view of the main portion of the manufacturing process of a film-shaped probe according to the first embodiment of the present invention;

FIG. 9B is a sectional view continued from FIG. 9A;

FIG. 9C is a sectional view continued from FIG. 9B;

FIG. 9D is a sectional view continued from FIG. 9C;

FIG. 10 is a sectional view of a main portion of a film-shaped probe according to the second embodiment of the present invention;

FIG. 11A is a sectional view of the main portion of the manufacturing process according to the third embodiment of the present invention;

FIG. 11B is a sectional view continued from FIG. 11A;

FIG. 11C is a sectional view continued from FIG. 11B;

FIG. 11D is a sectional view continued from FIG. 11C;

FIG. 12A is a sectional view of the main portion of the manufacturing process of a film-shaped probe according to the third embodiment of the present invention;

FIG. 12B is a sectional view continued from FIG. 12A;

FIG. 12C is a sectional view continued from FIG. 12B;

FIG. 12D is a sectional view continued from FIG. 12C; and

FIG. 13 is a sectional view of a main portion of a film-shaped probe according to the fourth embodiment of the present invention.

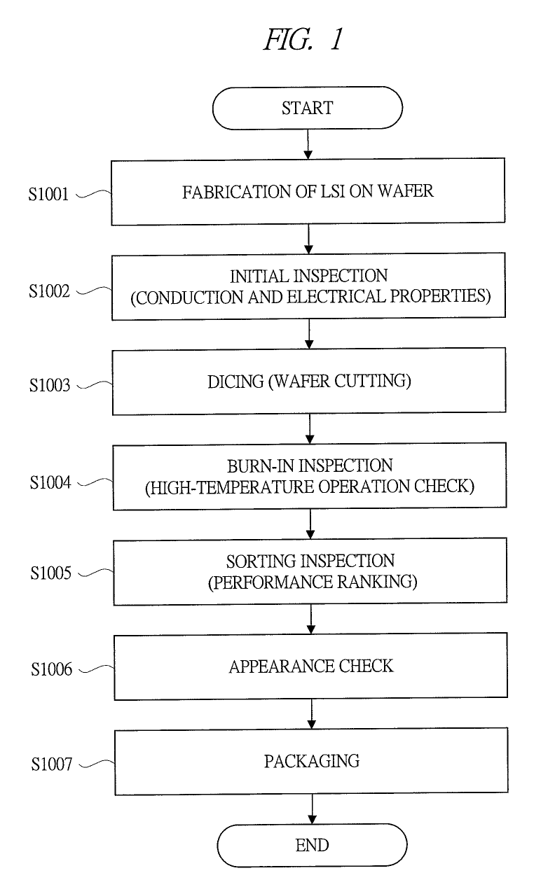

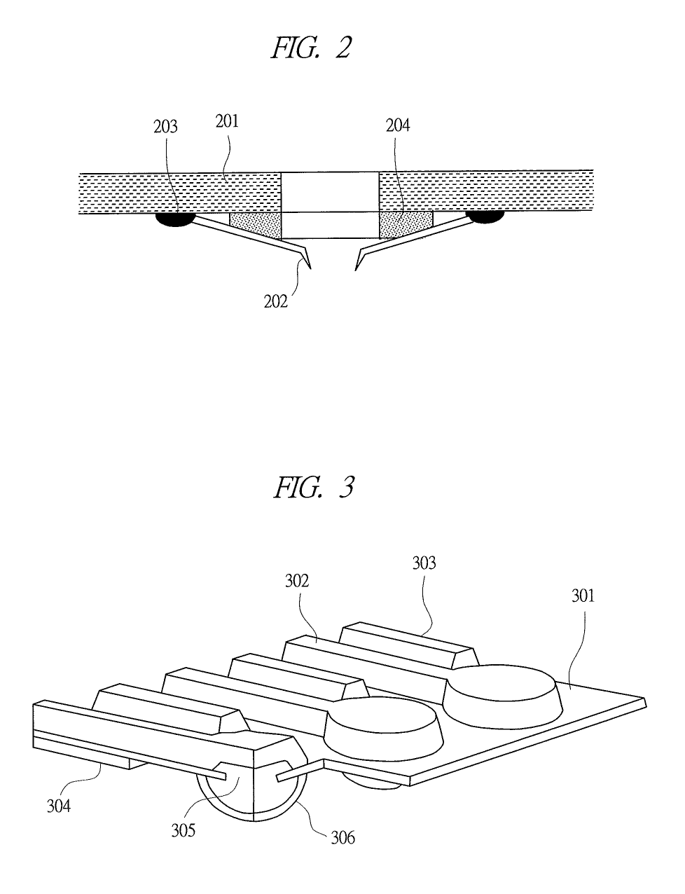

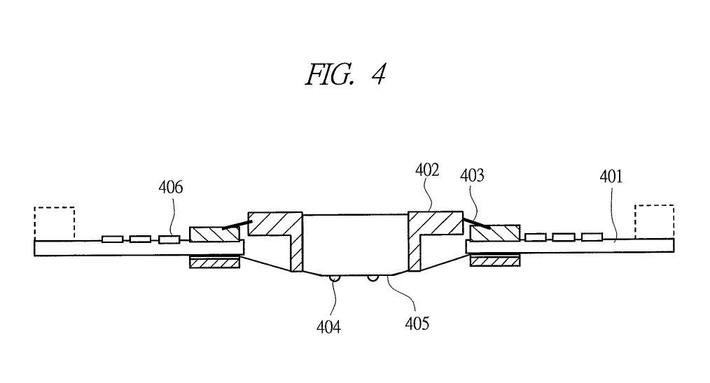

### DETAILED DESCRIPTION

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof. Also, in the embodiments described below, when referring to the number of elements (including number of pieces, values, amount, range, and the like), the number of the elements is not limited to a specific number unless otherwise stated or except the case where the number is apparently limited to a specific number in principle. The number larger or smaller than the specified number is also applicable.

Further, in the embodiments described below, it goes without saying that the components (including element steps) are not always indispensable unless otherwise stated or except the case where the components are apparently indispensable in principle. Also, even when mentioning that constituent elements or the like are “made of A” or “made up of A” in the embodiments below, elements other than A are of course not excluded except the case where it is particularly specified that A is the only element thereof.

Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the numerical value and the range described above.

Still further, when the materials and the like are mentioned, the specified material is a main material unless otherwise stated or except the case where it is not so in principle or situationally, and the secondary components, additives, additional components and the like are not excluded. For example, a silicon material includes not only the case of pure silicon but also secondary and ternary alloys (for example, SiGe) and the like formed of additive impurities and silicon as the main component unless otherwise stated.

Also, components having the same function are denoted by the same reference symbols throughout the drawings for describing the embodiments, and the repetitive description thereof is omitted.

Also, in some drawings used in the following embodiments, hatching is used even in a plan view so as to make the drawings easy to see.

Hereinafter, embodiments of the present invention will be described with reference to the drawings.

(Preliminary Study)

The inventors of the present invention have studied in detail a technique for solving the matters described in SUMMARY above.

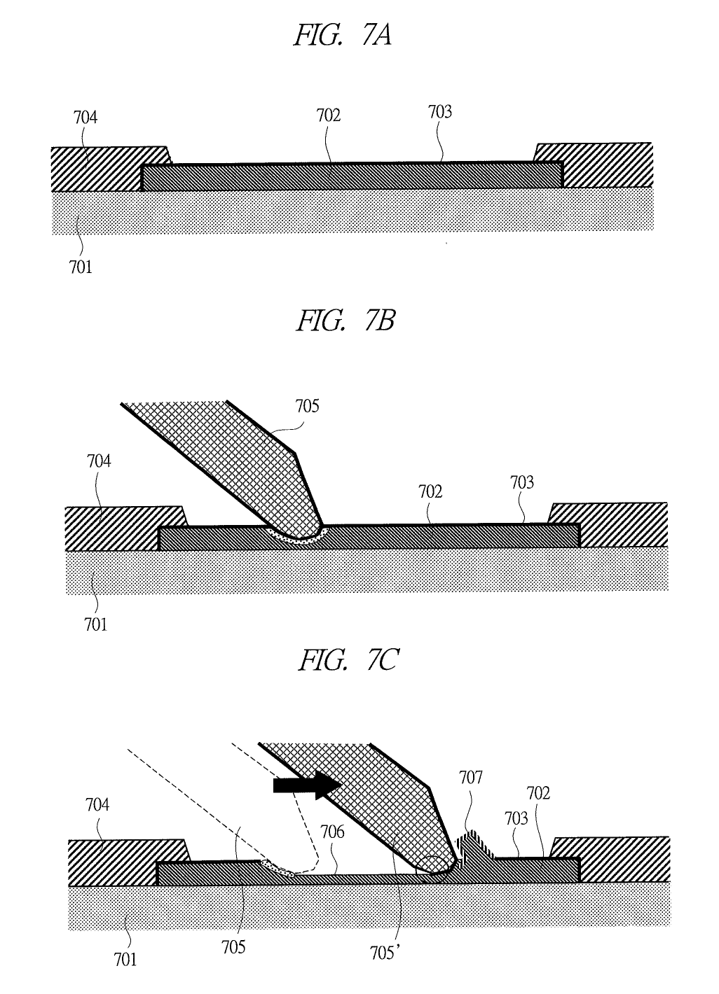

FIGS. 7A to 7C are explanatory diagrams showing a contact operation of a probe using a metal needle to an electrode.

As shown in FIG. 7A, an electrode 702 on an LSI formed on a surface of a silicon wafer 701 is made of a metal, and a typical material thereof is aluminum or aluminum alloy. Inmost metals, a surface thereof is naturally oxidized by atmospheric oxygen and thus a high-resistance oxide film 703 is formed on the surface. In particular, an aluminum oxide film is formed in a very short time and has also very high insulating properties, and therefore the oxide film 703 significantly hinders the measurement of electrical properties.

In practice, when seeing a portion that comes in actual contact with the electrode 702, a distal end of a probe 705 made of a hard metal, which is a conventional and typical probe, is formed with a curved face having a large radius of curvature in comparison to the film thickness of the electrode 702 as shown in FIG. 7B. This is because there is a risk that the load is concentrated at the contact point when the distal end of the probe comes into contact with the electrode if it is made very sharp, and the distal end sticks in the electrode to break the same. Therefore, as shown in FIG. 7B, even when the distal end of the probe 705 is just pressed onto the electrode 702, the depth of the insertion of the distal end is very shallow because the thickness of the electrode 702 is small, and it is difficult that the distal end surely penetrates the surface oxide film 703 to come into direct contact with a metal portion forming the electrode 702. Further, the oxide film 703 is often caught between the probe 705 and the electrode 702.

Therefore, in order to penetrate the oxide film 703 with the probe 705 to take conduction with a sufficiently low contact resistance, as shown in FIG. 7C, it is required to scratch the surface of the electrode 702 by moving the distal end of the probe 705 to a position 705′ while pressing the same against the electrode 702 so as to expose a newly-formed surface 706 without the oxide film 703, thereby bringing the probe 705′ into contact with the newly-formed surface 706.

However, such operation cannot always be controlled with a sufficient precision, and the probe 705′ itself runs onto a swell 707 of the surface pushed aside by the probe 705′ and cannot come into contact with the newly-formed surface 706 in some cases. Further, when the probe 705′ runs onto a protective film 704, the contact failure occurs, resulting in the reduction of the apparent manufacturing yield.

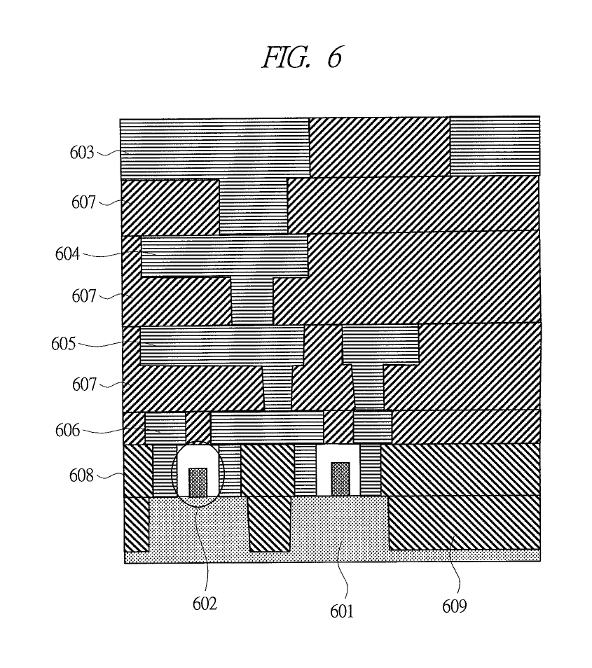

Furthermore, by moving the probe 705 while pressing the same against the surface of the electrode 702 in this manner, force that tears even the electrode 702 is generated. This force may be transmitted to the insulating layers (607, 608 and 609 in FIG. 6), the wirings (603, 604, 605 and 606 in FIG. 6) and the like under the electrode to break them.

Furthermore, there is a concern that the swell 707 on the surface of the electrode may drop off from the surface of the electrode to become a foreign matter on the wafer, which causes a plurality of electrodes 702 to be short-circuited.

In addition, since the metal film constituting the electrode 702 itself gets a large scratch, the scratch has a harmful influence on subsequent mounting steps such as wire bonding and plating bump formation, and this contributes to the reduction in yield. When considering these phenomena in combination, it is not desirable for LSI products in future to perform the operation of scratching a top of an electrode of the LSI by a probe.

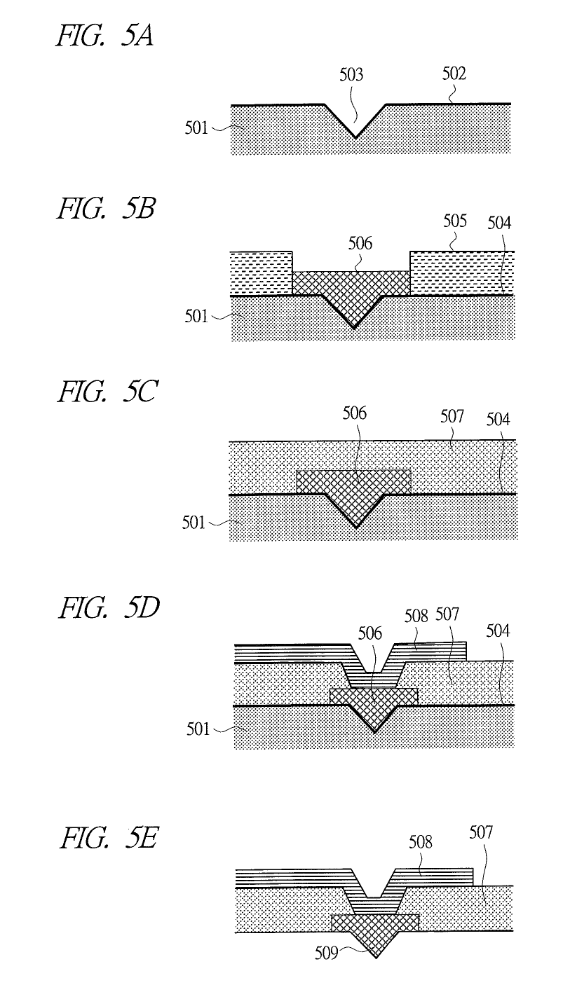

Further, the film-shaped probe in which a bump 306 formed by plating on a part of a wiring made of copper serves as a probe also has a disadvantage similar to the probe 705 using the hard metal needle described above because the contact terminal thereof is rounded. Furthermore, minute variations in height of the bumps 306 are inevitable due to the manufacturing method thereof, and the bumps 306 are connected to each other via an insulating resin sheet 301 and hardly move independently. Therefore, in the case where the bumps 306 include one bump slightly smaller in height and thus coming in insufficient contact, adjacent bumps 306 taller in height have to be shrunk by applying a large force in order to bring all the bumps 306 into complete contact, and therefore there is a problem that an excessive load is applied to the electrode 702 and its underlying structural body. This problem can also be seen in the film-shaped probe (see FIGS. 5A to 5E) in which the square pyramidal contacts are formed on the wirings formed on the flexible insulating film, and this problem is eased to some extent by some ideas, but cannot be completely prevented, and therefore this is a common problem due to the structure where the contacts are strongly connected to each other.

Among these problems, a basic idea for solving the trouble due to the penetration of the oxide film 703 on the surface of the electrode 702 is shown in the Patent Document 1. The trouble is solved by pressing the distal end of the contact terminal 509 having a sharp tip manufactured through the steps shown in FIGS. 5A to 5E vertically in the oxide film while controlling a load. The film-shaped probe has a great advantage that positional accuracy of the contact terminals is high because of its structure and manufacturing method and the contact terminals and the wirings can be formed at a narrow pitch. Therefore, it is guessed that a probe card according to the present invention adaptable to a narrow pad pitch LSI can achieve the object of the present invention by solving the problem of an excessive load caused by the slight variations in height of the distal ends of the contacts that is the disadvantage of the film-shaped probe.

The object of the present invention, that is, “to provide a probe card for LSI inspection that can achieve electrical conduction to electrodes with a low load without damaging the electrodes and a structural body therebelow even if the electrodes on the LSI are arranged at a narrow pitch and in a complex manner” can be achieved by solving the disadvantages of the film-shaped probe in which square pyramidal contact terminals that can obtain good electrical conduction are formed on the wirings formed on the flexible insulating film.

This film-shaped probe is also excellent in positional accuracy of the individual probes because of its structure and manufacturing method, and is sufficiently adaptable to the narrow-pitch electrode arrangement of about less than 50 μm.

Accordingly, regarding a contact terminal that causes a contact failure when a film-shaped probe is pressed onto a flat metal plate, the inventors of the present invention have first examined in detail the contact terminal itself and additionally a wiring layer and the like formed thereon. As a result, it has been found that the contact terminal that causes a contact failure occurs in most cases at a position having a portion whose upper layers and peripheries are different from those of the adjacent contact terminals in the arrangement of contact terminals and wirings corresponding to the arrangement of electrodes of an LSI.

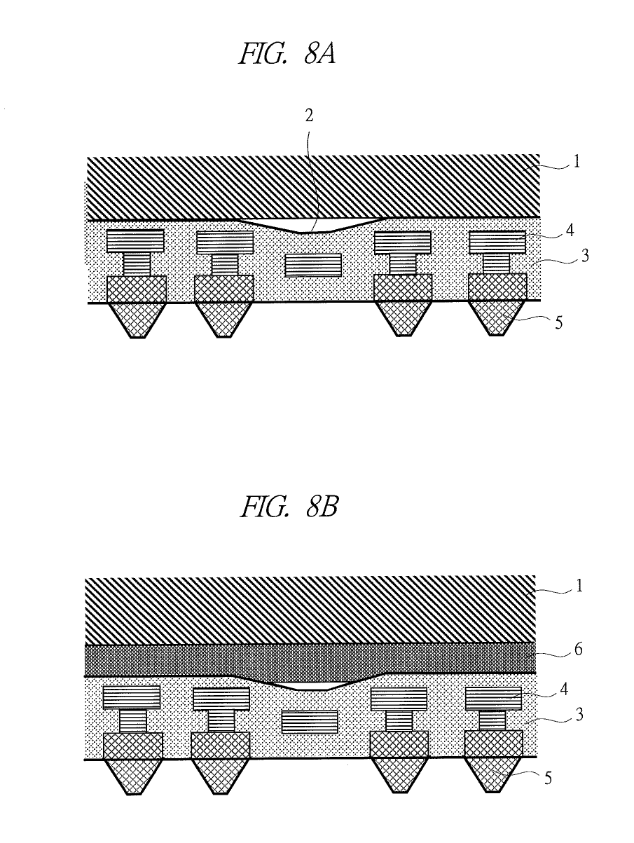

The contents thereof will be specifically described with reference to FIGS. 8A and 8B. FIGS. 8A and 8B are explanatory sectional views for improving the contact properties of a film-shaped probe.

As shown in FIG. 8A, a thin region 2 is formed in the film-shaped probe due to the arrangement of contact terminals 5 and wirings 4, and a rear side surface of the film-shaped probe of the contact terminals 5 adjacent to the thin region 2 is lower in height than that of other terminals. Therefore a portion at which the film-shaped probe is not in contact with a supporting plate 1 occurs. As a result, since the contact terminals 5 adjacent to the thin region 2 cannot receive sufficient force from the supporting plate 1 as compared with the other contact terminals 5, pressing force of the contact terminals 5 to the electrodes becomes insufficient and thus the contact failure occurs.

In order to absorb the local thickness variations of the film-shaped probe like this, the Patent Document 1 discloses a technique of sandwiching an elastomeric sheet 6 made of a sheet-like organic material between the supporting plate 1 and the film-shaped probe as shown in FIG. 8B. By this means, the contact properties are clearly improved. Alternatively, by making the film-shaped probe as thin as possible to make the whole of the film-shaped probe flexible to provide the contact terminals 5 with slight mobility in a vertical direction, an effect of absorbing the variations in height by the elastomeric sheet 6 is increased and the contact properties are further improved.

However, with the further increase in the number of electrodes and reduction in electrode arrangement pitch on a recent LSI, the above improvement effect tends to be decreased. This is partly due to that an interval between the probes that produces vertical mobility of the contact terminal 5 is reduced with the reduction in distance between the electrodes on the LSI and the effect obtained by thinning an insulating layer 3 and the like is offset, but the fact that the deformation of the elastomeric sheet 6 cannot follow the narrowed asperities of the film-shaped probe caused by narrowing the pitch has a larger influence thereon. In particular, it has been found that, when patterns such as the wiring 4 and the contact terminal 5 are not provided in the adjacent portion, the film surface dents by several to 10 μm with respect to the adjacent region to form a space, and since the elastomeric sheet 6 deforms due to applied pressure and escapes into the space at the time of contact, the contact pressure of the contact terminals adjacent to the dent is clearly reduced.

Because of these characteristics, a conventional film-shaped probe is inferior in terms of only the contact properties and the variations in load applied to the electrodes to a probe using hard metal needles which can move vertically and individually, and the adjustment for making the contact is difficult. Therefore, the film-shaped probe has not yet been used widely. On the basis of the findings, the present invention is aimed at fundamentally solving such variations in contact.

### First Embodiment

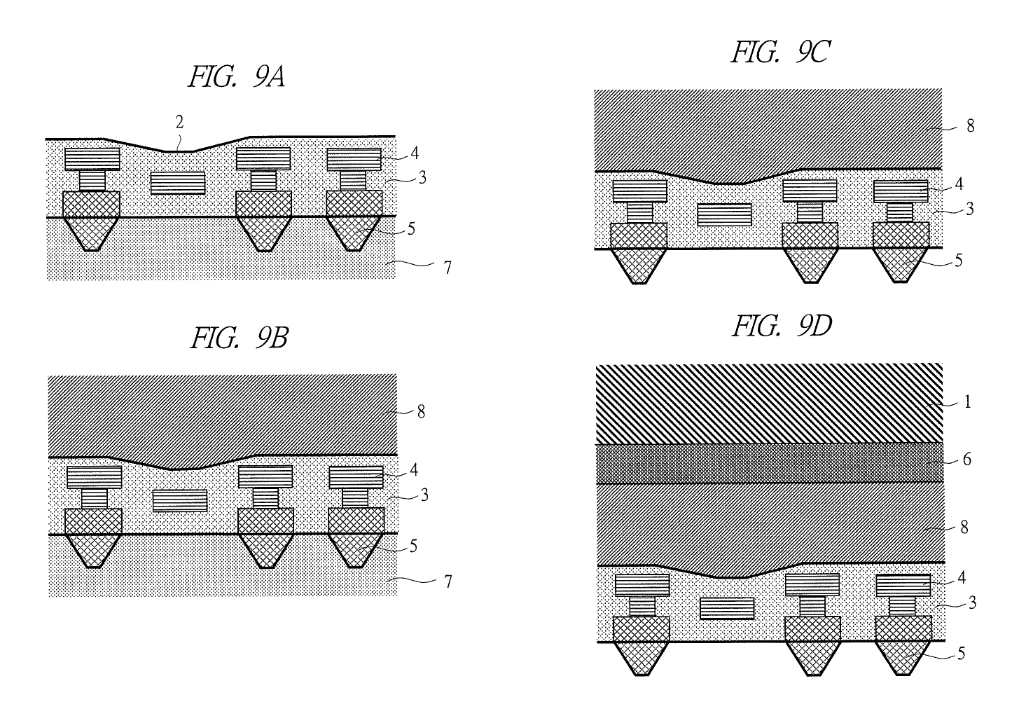

Based on the above-described preliminary study, the first embodiment of the present invention will be described with reference to FIGS. 5A to 5E and FIGS. 9A to 9D. FIGS. 9A to 9D show the main portions of the manufacturing process of a film-shaped probe according to the first embodiment of the present invention.

First, as shown in FIG. 5, on a surface of a silicon wafer 501 made of single crystalline silicon with a specific plane direction, a square pyramidal or truncated square pyramidal recess 503 is formed by an anisotropic etching technique (FIG. 5A). Thereafter, a copper thin film to be a plating base film 504 is formed to have a thickness of about 10 to 100 nm on a whole surface of the silicon wafer 501 by a sputtering technique.

Next, a resist pattern 505 having an opening above the square pyramidal or truncated square pyramidal recess is formed, and the square pyramidal or truncated square pyramidal recess is filled with a hard metal film 506 by an electroplating technique using the copper thin film to be the plating base film as an electric-supply film (FIG. 5B). A platinum group high-melting-point noble metal such as platinum, palladium, rhodium or iridium is suitable for a material of the hard metal. On this hard metal pattern, electro-nickel plating is successively performed to completely fill the recess 503. Finally, a distal end of the hard metal film 506 in the square pyramidal or truncated square pyramidal recess becomes a contact terminal 509. Since the electro-nickel plated film partially constituting the hard metal film 506 has a relatively low film stress, it is easy to form it thickly to fill the recess on the wafer. In particular, when sulfamate plating bath is used, there is no worries about the occurrence of abnormality such as deformation or cracking of the plating pattern.

Next, after the resist pattern 505 used as a mask for forming the hard metal film 506 is removed, polyimide varnish is applied onto the silicon wafer 501 and a curing baking process is then performed, thereby coating the hard metal film 506 with a resin layer 507 (FIG. 5C). Next, a resist pattern is formed on the resin layer 507 and the resin layer 507 just above the hard metal film 506 is partially removed by using a dry etching process, thereby forming a through hole (FIG. 5D).

Subsequently, a copper thin film to be a plating base film is formed by the sputtering technique on a surface of the resin layer 507 in which the through hole has been formed. Then, a resist pattern for forming a wiring is formed on the copper thin film, and electro-copper plating is performed by using the copper thin film, thereby forming a wiring 508 made of copper (FIG. 5E). Thereafter, the wiring 508 is separated by removing the unnecessary copper thin film between the wirings 508. Subsequently, a polyimide layer is formed on the whole surface of the wiring to form a protective layer for the wiring.

In this manner, a structural body shown in FIG. 9A is obtained. In the film-shaped probe in this state, as described above, a dent 2 occurs on a surface of the film-shaped probe due to the arrangement of the contact terminals 5 and the wirings 4 in most cases.

On this surface, a resin coating film 8 is formed by coating an upper surface of an area where at least the contact terminal 5 is formed (rear surface of the film-shaped probe) with liquid resin paste to be thicker than the polyimide layer and then curing the same as shown in FIG. 9B. For example, a resin that can be applied thickly such as epoxy resin, silicon resin, low-stress polyimide resin, polyamide resin or benzocyclobutene resin is assumed as the resin paste used here. Note that it is desired that a material for the resin paste has such properties as resistance to a heat of 100° C. or higher and resistance to deformation by repetitive pressing because it forms a part of the probe, but the material is not limited to these materials and can be widely selected in consideration of inspection conditions, load in the steps, material costs and others.

A resin paste is applied to the upper surface corresponding to the rear surface of the film-shaped probe. When liquid resin paste is applied, it flows so as to form a flat surface because of the nature of liquid and fills the dent 2 of the film-shaped probe, thereby smoothening the whole of the rear surface in the area where the contact terminal 5 is formed. Thereafter, the resin paste is cured by being left at room temperature or by heating to form a resin coating film 8.

However, the resin paste generally causes shrinkage in volume at its curing, and in particular, in the case of the paste obtained by dissolving resin into solvent, a volume reduction of several tens percent occurs in some cases. Therefore, for selecting a material of the paste, volume shrinkage at a curing time is also a criterion for determination. A material smaller in cure shrinkage can obtain the surface smoothness more easily regardless of the asperities of an underlying surface.

For example, when a percentage of shrinkage is 0.1%, even the thin coating with a film thickness of about 20 μm can obtain a large effect in surface smoothing. On the other hand, in a case of volume shrinkage of about 2 to 3%, if the coating has a small film thickness, surface asperities of a probe sheet appear on the surface of the resin film when the paste cures. Therefore, it is required to apply the paste as thick as about 50 to 100 μm.

In the application of the paste, it is possible to apply a spin coating method that utilizes the fact that the film-shaped probe at this time can be treated as a wafer because it is attached to a surface of the wafer with the contact terminals directed downward. In this case, an area where the paste must not be applied is preliminarily subjected to masking with an adhesive film or resist. Then, after the wafer is set on a spinner and the paste is dropped at the center of the wafer like in the ordinary photoresist, the wafer is rotated and coated with the paste.

When a material for the mask is an adhesive film, the film is removed after the application of the paste, and then the paste is cured, thereby forming the resin coating film at a desired position. When the material for the mask is a resist, after the paste is cured to form the coating film, the surface is mechanically polished to remove the paste on the resist, and then the resist is removed. Therefore, the cured object obtained from the resin material is required not to be dissolved by the liquid for removing the resist.

The resin coating film 8 is formed for improving the contact properties of the contact terminals 5. In this regard, it is mostly pointless to form the resin coating film 8 up to a portion far away from the contact terminals 5. However, if the resin coating film 8 is formed strictly and exclusively only just above the contact terminals 5, it projects by a thickness of the coating film as compared with portions around the contact terminals 5. This rather increases the asperities of the rear surface of the probe. For these reasons, it is preferred that the resin coating film 8 is formed so as to terminate at positions about 10 mm away from the contact terminals 5. Depending on the fluidity of the resin paste used as a material of the resin coating film 8, formation in a narrower region may provide a sufficient effect.

After the resin coating film 8 is formed in the above-described manner, the wafer 7 serving as a base of the film-shaped probe is removed like in a conventional example (FIG. 9C). This completes the film-shaped probe in which a surface on an opposite side to a surface of the contact terminals is flat. As a method of removing the wafer 7, namely, separating the wafer 7 from the film-shaped probe, a method of dissolving the wafer 7 with etching liquid is most suitable from the viewpoint of avoiding the damage to the film-shaped probe.

When the wafer is dissolved with the etching liquid, it is required to preliminarily form a barrier layer against silicon etching liquid on the surface of the wafer 7. As this barrier layer, a thermally-oxidized film 502 shown in FIG. 5A is used. In particular, a thermally-oxidized film formed by thermally oxidizing the silicon wafer 501 is preferred because it is dense and less defective.

The film-shaped probe formed in this manner has much smaller asperities on the rear surface of the contact terminals as compared with the film-shaped probe sheet formed according to a prior example. For example, even in a region where asperities with a difference in height of 5 to 10 μm occur on the surface of the film-shaped probe because of the presence and absence of underlayer wirings in a conventional example, the asperities can be reduced to 1 μm or less. Further, when a material having a percentage of cure shrinkage of 0.1% or less is selected for the resin material, the asperities can be suppressed to about 0.5 μm in some cases, and the film-shaped probe with almost no asperity can be achieved.

Note that, by incorporating the film-shaped probe sheet mounted with the elastomeric sheet 6 and the supporting plate 1 as shown in FIG. 9D as a probe card, a probe card remarkably superior to the film-shaped probe of the prior example in contact properties can be obtained.

The film-shaped probe thus manufactured can evenly push on the contact terminals, and therefore it becomes possible to press the contact terminals with an even pressure onto many pads of an object to be inspected.

### Second Embodiment

Next, the second embodiment of the present invention will be described.

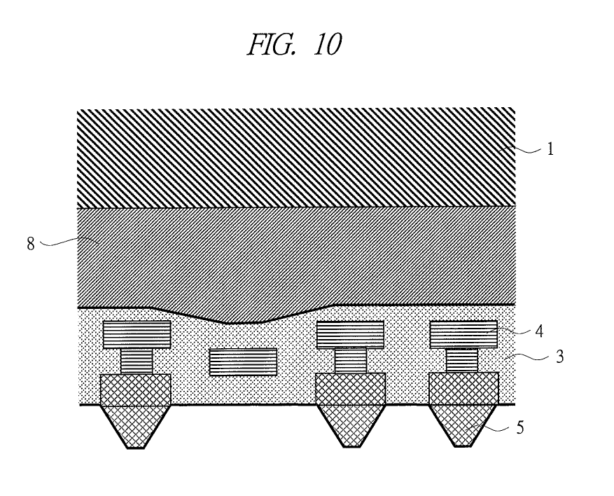

FIG. 10 is a sectional view of a main portion of a film-shaped probe according to the second embodiment of the present invention.

To apply a resin paste for forming the resin coating film 8 like in the first embodiment, selection of a material that is applicable as an elastomer such as silicon rubber for the resin material has also been considered. Using such a material eliminates the need for the elastomeric sheet 6 sandwiched between the film-shaped probe and the supporting plate 1 in the assembling process where the probe card is assembled as shown in FIG. 10. This makes it possible to mount the supporting plate directly on the film-shaped probe.

Further, if the supporting plate 1 is mounted on the uncured paste immediately after the application of the resin paste for forming the resin coating film 8, the resin paste is sandwiched between the supporting plate 1 and the film-shaped probe and a space between the film-shaped probe and the supporting plate 1 is all filled with the resin paste.

By adopting the process described above, not only the asperities of the surface of the film-shaped probe can be eliminated to a high degree, but also the shrinkage due to internal stress of the film-shaped probe generated inevitably when a substrate on which the film-shaped probe is formed is finally removed can be suppressed. Therefore, since the positional accuracy of the contact terminals is remarkably improved and it is possible to reduce the positional error to one-third as far as the inventors of the present invention have examined, there is an advantage that the positional errors of the contact terminals of the film-shaped probe can be practically eliminated.

### Third Embodiment

Next, the third embodiment of the present invention will be described.

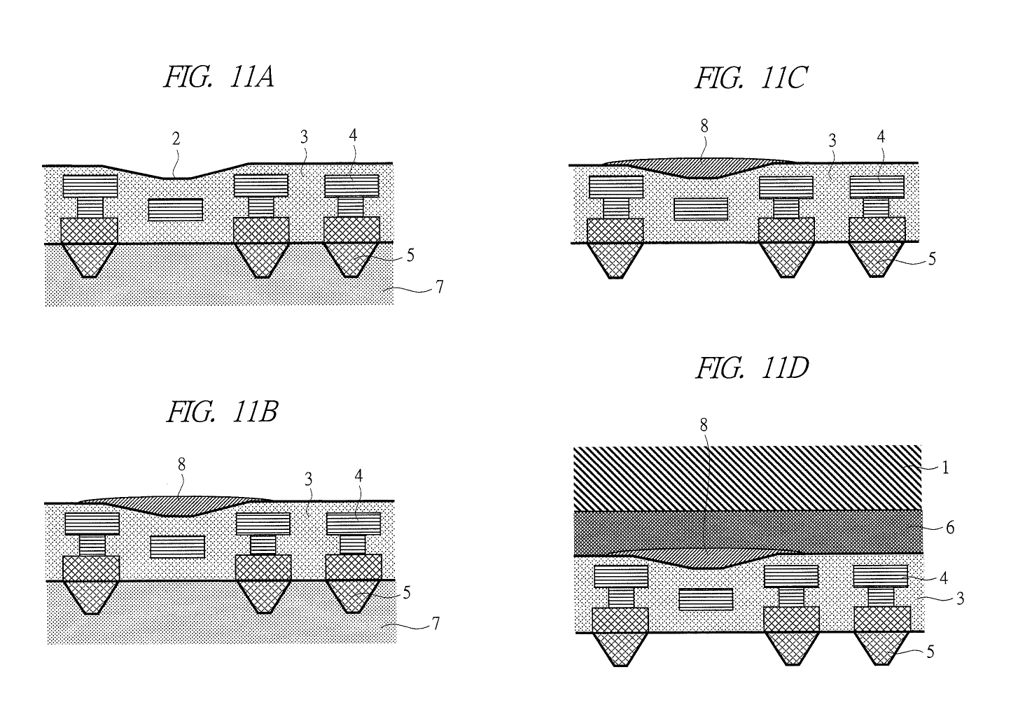

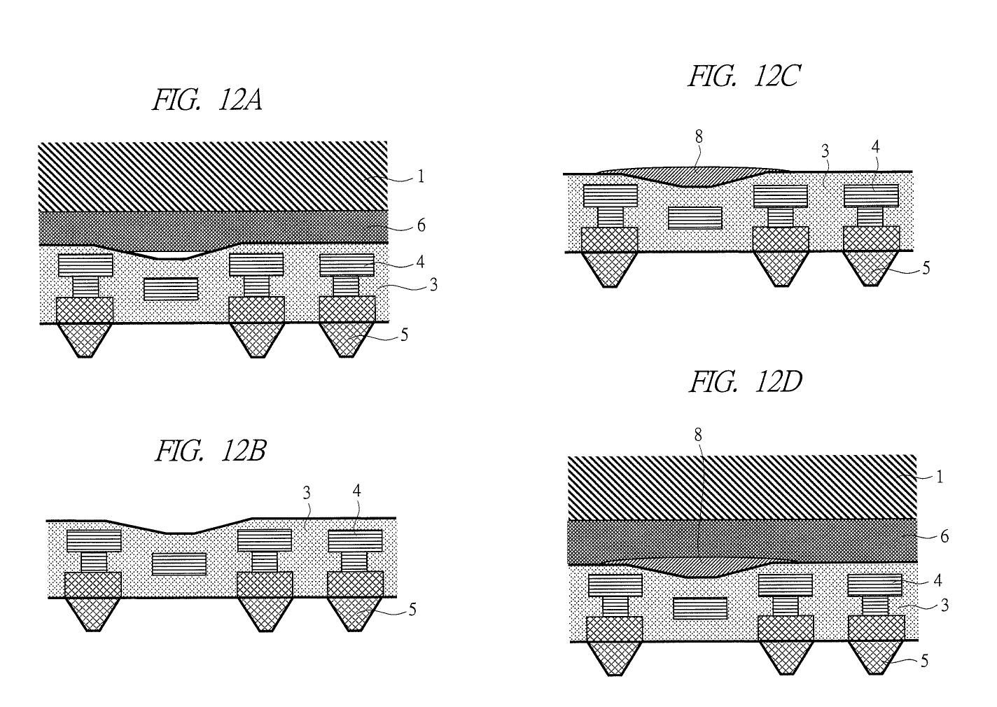

FIG. 11A to 11D show the main portions of the manufacturing process according to the third embodiment of the present invention. FIGS. 12A to 12D show the main portions of the manufacturing process for a film-shaped probe according to the third embodiment of the present invention.

The film-shaped probe is completed by the manufacturing process shown in FIGS. 5A to 5E in the same manner as the second embodiment to obtain the state shown in FIG. 11A. At this time, since the film-shaped probe is attached to the wafer 7 or a substrate surface with the contact terminals 5 facing downward, the film-shaped probe can be treated as a wiring layer of the wafer 7 or the substrate surface.

Therefore, as shown in FIG. 11B, the resin paste for forming the resin coating film 8 is applied and printed to a desired position of the film-shaped probe by using a mask such as a screen plate, and it is then cured. By this means, the dent of the wiring layer can be filled.

However, unlike the first embodiment, if the resin paste is applied on an originally flat portion on a surface of the insulating layer 3, the portion forms a projection and a dent relatively occurs at a portion adjacent to the projection, resulting in the deterioration of the contact properties. Therefore, it is required to grasp where the dent occurs from wiring patterns in advance.

In the printing, the plate is aligned while watching the pattern of the wirings 4 of the film-shaped probe on the wafer 7. Since the resin paste for forming the resin coating film 8 can be printed within the positional error of about ±10 μm, it is possible to apply the paste to an area needed in accordance with the wiring pattern of the film-shaped probe.

The rear surface of the film-shaped probe thus manufactured can be a surface having a sufficient smoothness though it is not as smooth as that of the first embodiment. After the resin paste is cured to form the resin coating film 8, the wafer 7 is removed as shown in FIG. 11C, whereby the film-shaped probe having a smooth rear surface can be obtained.

In this example, it is necessary to set the printing conditions of paste in conformity with the cure shrinkage of the resin paste for forming the resin coating film 8 and the spreading of the paste after printing. However, since the resin paste can be effectively utilized, it is advantageous in material cost.

Further, in the structure in which thick resin layers are entirely stacked like in the first embodiment, a negative effect may occur due to overlapping of thermal expansions and mechanical characteristics of the resin layers with mechanical characteristics of the film-shaped probe. Since the amount of the resin paste to be applied is very small in this third embodiment, the mechanical and thermal characteristics of the film-shaped probe remain as they are even after the application, and a new negative effect does not occur.

After the applied resin paste is cured, the film-shaped probe with a flat and smooth surface can be obtained by removing the wafer 7 as shown in FIG. 11C. Then, by mounting the elastomeric sheet 6 and the supporting plate 1 onto the film-shaped probe to assemble them as a probe card, the probe card excellent in contact properties can be completed (FIG. 11D).

Note that, as the means for locally applying the paste as described above, a dispenser that pushes out and applies the resin paste for forming the resin coating film 8 by air pressure or the like can be used instead of the printing. More specifically, a small amount of the resin paste is dropped onto the surface of the film-shaped probe by the dispenser having a syringe set at its distal end, and the resin paste is cured after it is wet spread sufficiently.

When using the dispenser, since a position to be applied can be specified in an application step, it is unnecessary to prepare a mask in advance unlike the case of printing. Therefore, there is an advantage that the manufacturing cost and manufacturing period for the mask become unnecessary. On the other hand, when using the dispenser, the resin paste is sequentially applied to positions one by one. Therefore, there is also a disadvantage that the time for the step is elongated when the number of positions to be applied is large.

As a method similar to that using the dispenser, it is also possible to apply the resin paste for forming the resin coating film 8 by using a prober to which thin metal wires are set. Further, if the wiring pattern is not fine, a human can use such a tool as thin wires or brush to apply the resin paste manually.

Also, the above-described method of applying the paste one by one is characterized in that the resin paste can be applied not only to the film-shaped probe in the state of being attached to the wafer 7 or a substrate but also to the film-shaped probe after completed as a film-shaped probe.

Therefore, the following example can be applied as an advantageous embodiment of these application methods.

That is, as shown in FIG. 12A, the film-shaped probe manufactured by a conventional method is first assembled as a probe card, and then the probe card is disassembled as shown in FIG. 12B to take out the film-shaped probe. Thereafter, the resin paste for forming the resin coating film 8 is applied as shown in FIG. 12C above the checked contact terminals, and then the film-shaped probe is reassembled as the probe card as shown in FIG. 12D.

In this method, since the contact terminal that is actually in a poor contact state is repaired, the probe card can be modified after finally checking the problem of the low contact pressure that is due only to the film-shaped probe. In this point, this method is very advantageous as a method of adjusting the contact properties of the probe card.

### Fourth Embodiment

Next, the fourth embodiment will be described.

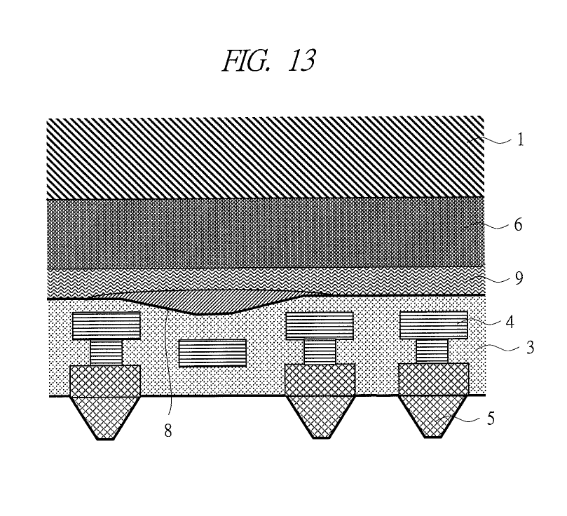

FIG. 13 is a sectional view of a main portion of a film-shaped probe according to the fourth embodiment of the present invention.

The resin coating film 8 is locally applied and cured at the dent portion of the film-shaped probe by the methods described in the second embodiment and the third embodiment, and the film-shaped probe without a dent on its surface can be obtained. Therefore, an elastic sheet purely focusing on its mechanical characteristics can be selected and sandwiched as an elastomer sandwiched between the film-shaped probe and the supporting plate in order to absorb an impact load when the electrodes of the LSI to be inspected and the probes are brought into contact with each other, regardless of additionally needed characteristics such as flexibility for covering the dent of the film-shaped probe sheet and coating and curing properties of the paste unlike a conventional example.

Therefore, it is also possible to sandwich a plurality of elastic sheets in order to achieve intended characteristics if needed.

For example, as shown in FIG. 13, it is possible to form a probe card excellent in durability by such an optimum combination in which a hard resin sheet 9 is mounted on the film-shaped probe so as to reinforce the film-shaped probe and prevent the deformation thereof due to repetitive impact loads and the elastomeric sheet 6 is mounted thereon so as to absorb the impact loads transmitted from the hard metal film 5.

Furthermore, it is also possible to fix one or more than one elastomer and supporting plate 1 to the film-shaped probe. The film-shaped probe to which the elastomer and the supporting plate 1 are fixed and an LSI to be inspected may be commercially sold in a set.

As described above, by smoothening the surface of the film-shaped probe on the rear side of the contact terminals after the formation of the probe, the influence from the layout of the contact terminals and the wirings extended from the contact terminals to the periphery of the probe can be eliminated. Therefore, even if the pads of an object to be inspected are arranged at a narrow pitch and in a complex manner, the variations in pressing force among the contact terminals that occur in a conventional example can be significantly suppressed, and the inspection can be performed without applying excessive pressing force.

In the foregoing, the invention made by the inventors of the present invention has been concretely described based on the embodiments. However, it is needless to say that the present invention is not limited to the foregoing embodiments and various modifications and alterations can be made within the scope of the present invention.

### INDUSTRIAL APPLICABILITY

The present invention can be widely applied to a probe card and a manufacturing method of a semiconductor device.

What is claimed is:

1. A probe card comprising:
a plurality of contact terminals that are brought into contact with a plurality of electrodes mounted on an object to be inspected;
pads formed integrally with the contact terminals;
wirings extended from the respective pads;
a resin film covering the pads and the wirings; and
a film-shaped probe in which a plurality of peripheral electrodes electrically connected to the wirings and connected to electrodes on an external wiring board are formed,
wherein, on a rear surface on an opposite side to a main surface of the film-shaped probe on which the contact terminals are exposed, a resin paste is applied at least to a region corresponding to a portion immediately above the contact terminals, and is then cured.

2. The probe card according to claim 1,
wherein a main component of the resin paste applied to the film-shaped probe is cured at room temperature or by heating, and a cured object thereof has a thermal resistance of 100° C. or higher.

3. The probe card according to claim 1,
wherein an end of the region where the resin paste is applied is within 10 mm from one of the contact terminals that is closest thereto.

4. The probe card according to claim 1,
wherein a difference in height in surface asperities of a resin layer on which the resin paste has been cured is 1 μm or less.

5. The probe card according to claim 1,
wherein a plate member made of metal or ceramics is directly mounted on a resin after applying the resin paste or after curing the resin paste.

6. The probe card according to claim 1,
wherein one or a plurality of resin sheets is mounted on the cured resin paste, and a plate member made of metal or ceramics is mounted on the one or the plurality of resin sheets.

7. The probe card according to claim 1,
wherein the application and curing of the resin paste are performed during a process of forming the film-shaped probe.

8. The probe card according to claim 1,
wherein the application and curing of the resin paste are performed in combination with inspection of contact properties of the film-shaped probe after assembly of the probe card.

9. The probe card according to claim 1,
wherein the resin paste to be applied is a material having a percentage of cure volume shrinkage of 1% or less.

10. The probe card according to claim 1,
wherein the resin paste is applied to a rear surface of the film-shaped probe above all the contact terminals formed on the probe card.

11. The probe card according to claim 1,
wherein the resin paste is applied to a rear surface of the film-shaped probe above a specific terminal or a specific terminal group of the contact terminals formed on the probe card.

12. The probe card according to claim 1,
wherein at least one elastomeric sheet is stacked on a surface of the film-shaped probe on an opposite side to the contact terminals, and a plate member made of metal or ceramics is mounted on the elastomeric sheet.

13. A method of manufacturing a semiconductor integrated circuit device, comprising the steps of:
providing a semiconductor integrated circuit device with a plurality of electrodes; and
inspecting the semiconductor integrated circuit device by using a probe card,
the probe card comprising:
a plurality of contact terminals that are brought into contact with the plurality of electrodes;
pads formed integrally with the contact terminals;
wirings extended from the respective pads;
a resin film covering the pads and the wirings; and
a film-shaped probe in which a plurality of peripheral electrodes electrically connected to the wirings and connected to electrodes on an external wiring board are formed,
wherein, on a rear surface on an opposite side to a main surface of the film-shaped probe on which the contact terminals are exposed, a resin paste is applied at least to a region corresponding to a portion immediately above the contact terminals, and is then cured.

14. The method according to claim 13,
wherein a main component of the resin paste applied to the film-shaped probe is cured at room temperature or by heating, and a cured object thereof has a thermal resistance of 100° C. or higher.

15. The method according to claim 13,
wherein an end of the region where the resin paste is applied is within 10 mm from one of the contact terminals that is closest thereto.

16. The method according to claim 13,
wherein a difference in height in surface asperities of a resin layer on which the resin paste has been cured is 1 μm or less.

17. The method according to claim 13,
wherein a plate member made of metal or ceramics is directly mounted on a resin after applying the resin paste or after curing the resin paste.

18. The method according to claim 13,
wherein one or a plurality of resin sheets is mounted on the cured resin paste, and a plate member made of metal or ceramics is mounted on the one or the plurality of resin sheets.

19. The method according to claim 13,
wherein the application and curing of the resin paste are performed during a process of forming the film-shaped probe.

20. The method according to claim 13,
wherein the application and curing of the resin paste are performed in combination with inspection of contact properties of the film-shaped probe after assembly of the probe card.
